(19) United States
(12) Patent Application Publication
(10) Pub. No.: US 2012/0217653 A1
(43) Pub. Date: Aug. 30, 2012

(54) SEMICONDUCTOR DEVICE AND NOISE SUPPRESSING METHOD

(75) Inventors: Koichi Takemura, Tokyo (JP); Hisashi Ishida, Tokyo (JP)

(73) Assignee: NEC CORPORATION, Tokyo (JP)

(21) Appl. No.: 13/508,073

(22) PCT Filed: Sep. 1, 2010
(86) PCT No.: PCT/JP2010/005391

§ 371 Date: May 4, 2012

(30) Foreign Application Priority Data
Nov. 10, 2009 (JP) 2009-257070

(51) Int. Cl. H01L 23/48

(52) U.S. Cl. 257/774; 257/E23.01

(57) ABSTRACT

A first semiconductor chip (200) is mounted on a second semiconductor chip (100). The first semiconductor chip (200) has a first conductor pattern (222). The second semiconductor chip (100) has a second conductor pattern (122). The second conductor pattern (122) is formed at a region overlapping the first conductor pattern (222) in a plan view. At least one element selected from a group consisting of the first conductor pattern (222) and the second conductor pattern (122) has a repetitive structure.

### TECHNICAL FIELD

The present invention relates to a semiconductor device mounting a semiconductor chip on a mounted object and to a noise suppressing method.

### BACKGROUND ART

Examples of a mounting method of a semiconductor chip include a flip-chip mounting technology to mount the semiconductor chip on an interposer substrate. In this method, the semiconductor chip is so arranged that its face provided with an interconnect layer faces the interposer side, and thus the interposer substrate and the semiconductor chip are connected to each other through a bump.

Moreover, in recent years, a three-dimensional mounting structure has been also suggested. In this structure, a plurality of semiconductor chips are stacked in the same direction as each other, and the semiconductor chips are connected to each other through a through-via that penetrates substrates of the semiconductor chips.

Japanese Laid-open Patent Publication No. 2008-270363 discloses to provide a dielectric substrate with an EBG structure in a high-frequency package for mounting a high-frequency semiconductor on the dielectric substrate in a flip-chip manner. According to this technology, a through-hole making up the EBG structure attenuates electromagnetic waves, and this improves an isolation characteristic of a high frequency between an input and an output of the high-frequency semiconductor.

### RELATED DOCUMENT

### Patent Document

[Patent Document 1] Japanese Laid-open Patent Publication No. 2008-270363

### DISCLOSURE OF THE INVENTION

In the above-described flip-chip mounting or three-dimensional mounting structure, a semiconductor chip and a mounted object such as a lower-side semiconductor chip and an interposer substrate are connected to each other through a connection member such as a bump. This connection member is located at a space between the semiconductor chip and the mounted object. As a result, the electromagnetic waves radiated from the connection member may leak to the outside through the space between the semiconductor chip and the mounted object and become a noise.

An object of the invention is to provide a semiconductor device and a noise suppressing method capable of preventing electromagnetic waves from leaking to the outside through a space between a semiconductor chip and a mounted object.

According to one embodiment of the invention, there is provided a semiconductor device including:

a mounted object;

a first semiconductor chip mounted over the mounted object;

a plurality of first conductors repeatedly provided to one element selected from a group consisting of the first semiconductor chip and the mounted object;

a second conductor provided to the other element selected from the group consisting of the first semiconductor chip and the mounted object, the second conductor being opposite to the plurality of first conductors; and

a plurality of connection members provided at a space between the mounted object and the first semiconductor chip, the plurality of connection members being electrically connecting the plurality of first conductors to the second conductor,

wherein the plurality of first conductors are electrically connected to each other through the plurality of connection members and the second conductor.

According to another embodiment of the invention, there is provided a semiconductor device including:

a mounted object;

a first semiconductor chip mounted over the mounted object;

a plurality of first conductors repeatedly provided to one element selected from a group consisting of the mounted object and the first semiconductor chip;

a second conductor provided to the one element, the second conductor being opposite to the plurality of first conductors;

a plurality of vias connecting the plurality of first conductors to the second conductor,

wherein the plurality of first conductors are electrically connected to each other through the plurality of vias and the second conductor.

According to still another embodiment of the invention, there is provided a noise suppressing method including:

providing a first conductor to a mounted object over which a semiconductor chip is mounted; and

providing a second conductor to the semiconductor chip, the second conductor being located at a region opposite to the first conductor,

wherein at least one element selected from a group consisting of the first conductor and the second conductor is formed to have a repetitive structure, and an Electromagnetic Band Gap (EBG) structure is formed by using the first conductor and the second conductor,

the method being preventing a noise from leaking from a space between the mounted object and the first semiconductor chip.

The present invention makes it possible to prevent electromagnetic waves from leaking to the outside through a space between the semiconductor chip and the mounted object.

### BRIEF DESCRIPTION OF THE DRAWINGS

The above and other objects, features and advantages of the present invention will be more apparent from the following preferred embodiments and the accompanying drawings.

FIG. 1 shows a cross-sectional diagram illustrating a configuration of a semiconductor device according to a first embodiment.

FIG. 2 shows an enlarged cross-sectional diagram illustrating a configuration of a connection portion between an upper-side semiconductor chip and a lower-side semiconductor chip.

FIG. 3 shows a planar schematic diagram illustrating a positional relationship between a first region and an EBG structure.

FIG. 4 shows a cross-sectional diagram illustrating a configuration of a semiconductor device according to a second embodiment.

FIG. 5 shows a cross-sectional diagram illustrating a configuration of a semiconductor device according to a third embodiment.

FIG. 6 shows a cross-sectional diagram illustrating a configuration of a semiconductor device according to a fourth embodiment.

FIG. 7 shows a cross-sectional diagram illustrating a configuration of a semiconductor device according to a fifth embodiment.

FIG. 8 shows a cross-sectional diagram illustrating a configuration of a semiconductor device according to a sixth embodiment.

FIG. 9 shows a cross-sectional diagram illustrating a configuration of a semiconductor device according to a seventh embodiment.

FIG. 10 shows a cross-sectional diagram illustrating a configuration of a semiconductor device according to an eighth embodiment.

FIG. 11 shows a cross-sectional diagram illustrating a configuration of a semiconductor device according to a ninth embodiment.

FIG. 12 shows a cross-sectional diagram illustrating a configuration of a semiconductor device according to a tenth embodiment.

FIG. 13 shows a cross-sectional diagram illustrating a configuration of a semiconductor device according to an eleventh embodiment.

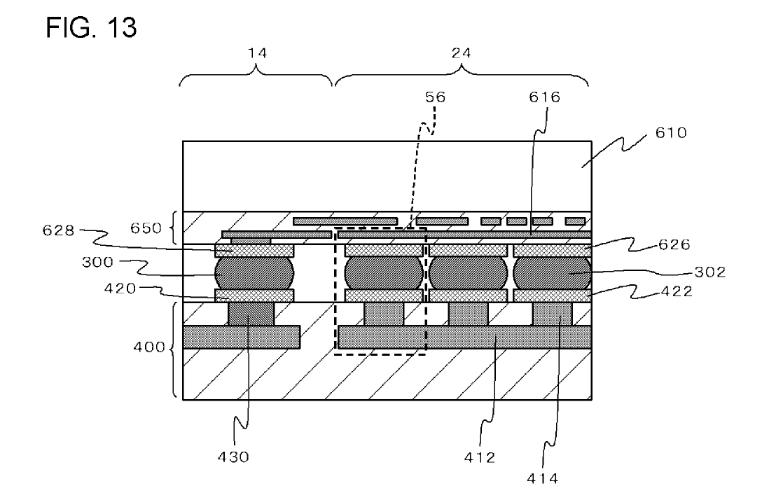

### DESCRIPTION OF EMBODIMENTS

Hereinafter, embodiments of the invention will be described with reference to the attached drawings. In all of the drawings, like reference numerals will be given to like parts having substantially the same functions, and description thereof will not be repeated.

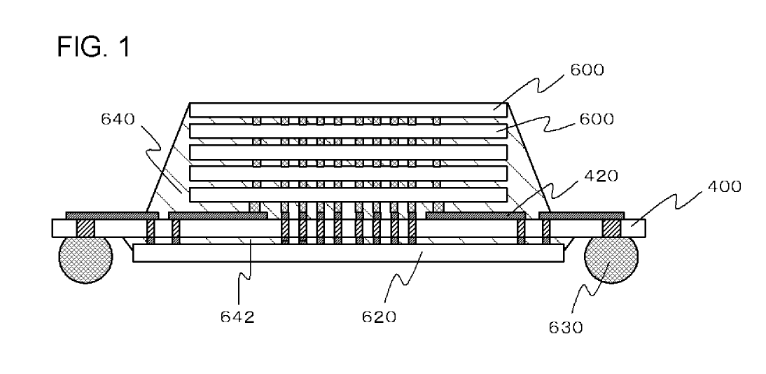

FIG. 1 shows a cross-sectional diagram illustrating a configuration of a semiconductor device according to a first embodiment. This semiconductor device includes an interposer substrate 400, a plurality of semiconductor chips 600, a semiconductor chip 620, and solder balls 630 serving as external connection terminals. The plurality of semiconductor chips 600 are memory chips and are stacked on one face of the interposer substrate 400. The semiconductor chip 620 is a system LSI, and is mounted on the other face of the interposer substrate 400. The plurality of semiconductor chips 600 and the semiconductor chip 620 overlap each other in a plan view.

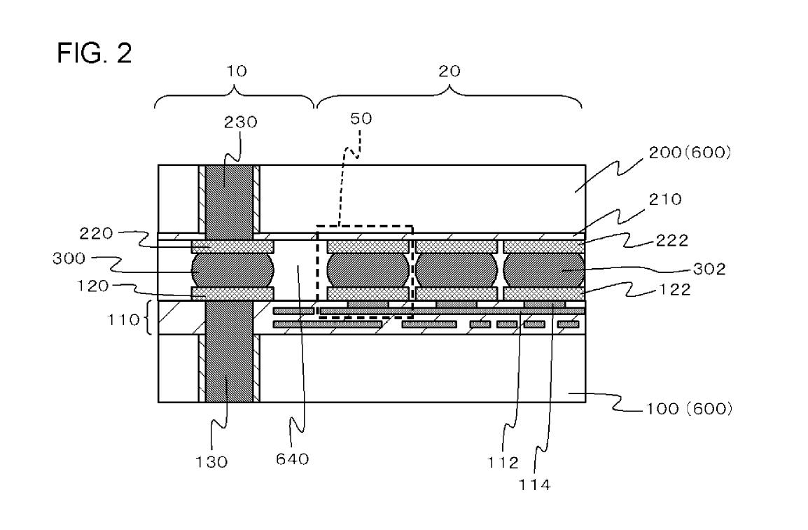

The semiconductor chips 600 are stacked in a manner such that its active face, that is, a face on which an element such as a transistor, a multi-layer wiring, and a redistribution layer are formed faces an opposite direction with respect to the interposer substrate 400. Each of the semiconductor chips 600 has a through-via (shown in FIG. 2), and is connected through the through-via to the other semiconductor chip 600 or the interposer substrate 400 located at the lower side. A through-via of the lowest semiconductor chip 600 is connected to the semiconductor chip 620 through a via and an interconnect provided to the interposer substrate 400.

Each of the solder balls 630 is an external connection terminal for connecting the semiconductor device to a main board or the like, and is provided on the face of the interposer substrate 400 on which the semiconductor chip 620 is mounted. The solder ball 630 and the semiconductor chip 620 are connected to the solder ball 630 through a via and an interconnect provided to the interposer substrate 400.

The plurality of semiconductor chip 600 is sealed by encapsulation resin 640 on the one face of the interposer substrate 400, and the semiconductor chip 620 is sealed by encapsulation resin 642 on the other face of the interposer substrate 400.

FIG. 2 shows an enlarged cross-sectional diagram illustrating a configuration of a connection portion between a first semiconductor chip 200 and a second semiconductor chip 100. The first semiconductor chip 200 is the upper-side semiconductor chip 600. The second semiconductor chip 100 is the lower-side semiconductor chip 600. In an example shown in this drawing, the first semiconductor chip 200 is mounted on the second semiconductor chip 100. The first semiconductor chip 200 has first conductor patterns 222 cut into conductor pieces, and the second semiconductor chip 100 has conductor patterns 122 connected to the first conductor patterns 222 cut into conductor pieces. Each of the conductor patterns 122 is formed at the region overlapping each of the first conductor patterns 222 cut into conductor pieces in a plan view. In the first conductor patterns 222 cut into conductor pieces and the conductor patterns 122, at least the first conductor patterns 222 cut into conductor pieces have a repetitive structure, for example, a periodic structure. The first conductor patterns 222 and the second conductor patterns 122 make up at least a part of an Electromagnetic Band Gap (EBG) structure 20. That is, in this embodiment, the conductor patterns 122 and the first conductor patterns 222 cut into conductor pieces have a repetitive structure at the regions where they face each other, and this repetitive structure is formed spanning from the second semiconductor chip 100 to the first semiconductor chip 200 in a thickness direction. The repetitive structure is connected to one element selected from a group consisting of the conductor pattern 122 and the first conductor pattern 222 cut into conductor pieces that includes the repetitive structure.

In the example shown in the drawing, the first conductor patterns 222 cut into conductor pieces are formed on the face of the first semiconductor chip 200 opposite to the second semiconductor chip 100. The conductor patterns 122 are formed on the face of the second semiconductor chip 100 opposite to the first semiconductor chip 200.

The second semiconductor chip 100 includes a multi-layer wiring 110 and a redistribution layer on the face opposite to the first semiconductor chip 200 for a stacking structure to stack a conductor layer and an insulating layer in a repetitive manner. The redistribution layer includes a plurality of island-shaped conductor patterns serving as the conductor patterns 122. The multi-layer wiring 110 includes a sheet-shaped first conductor plane 112 and a plurality of vias 114. The plurality of island-shaped conductor patterns serving as the conductor patterns 122 are periodically arranged. The first conductor plane 112 is located at a lower layer in relation to the conductor patterns 122, and extends in the region overlapping the conductor patterns 122 in a plan view. The plurality of vias 114 connect each of the plurality of island-shaped conductor patterns serving as the conductor patterns 122 to the first conductor plane 112. The first conductor plane 112 is connected to either a power supply line or a ground line, for example, the power supply line.

The first conductor patterns 222 cut into conductor pieces are island-shaped conductor patterns formed in an island shape at each position overlapping the plurality of island-shaped conductor patterns serving the conductor patterns 122 in a plan view. In addition, the meaning of “island-shaped” is that the first conductor patterns 222 cut into conductor pieces are isolated from each other in a layer, and the shape of the first conductor patterns 222 cut into conductor pieces is not simply limited to a quadrilateral, a circle, or the like, and may be a shape such as a line, a planar coil formed by winding the line, or the like. The first semiconductor chip 200 includes an insulting layer 210. The insulting layer 210 is located between the first conductor patterns 222 cut into conductor pieces and a substrate. In the example shown in this drawing, the insulting layer 210 is provided on the rear surface of a substrate of the first semiconductor chip 200. The first conductor patterns 222 cut into conductor pieces are formed on the insulting layer 210. The insulting layer 210 is formed of, for example, a silicon oxide film, a silicon nitride film, or a silicon oxynitride film.

The semiconductor device shown in FIG. 2 includes a plurality of bumps 302 serving as a connection member. Each of the bumps 302 connects each of the plurality of island-shaped conductor patterns serving as the conductor patterns 122 to any one of the plurality of island-shaped conductor patterns serving as the first conductor patterns 222 cut into conductor pieces. In the first semiconductor chip 200, the first conductor patterns 222 are electrically independent from other conductors included in the first semiconductor chip 200. In this embodiment, the first conductor patterns 222 are not directly connected to other conductors included in the first semiconductor chip 200. The plurality of first conductor patterns 222 are electrically connected to each other through the plurality of bumps 302, the plurality of conductor patterns 122, the plurality of vias 114, and the conductor pattern 112.

The first semiconductor chip 200 has a through-via 230, and the second semiconductor chip 100 has a through-via 130. One end of the through-via 230 is connected to an electrode pad 220 serving as a first external connection terminal, and one end of the through-via 130 is connected to an electrode pad 120 serving as a second external connection terminal. The electrode pad 220 is formed on the face of the first semiconductor chip 200 opposite to the second semiconductor chip 100, that is, in the redistribution layer. The electrode pad 220 is positioned in the same layer as the first conductor patterns 222 cut into conductor pieces. The electrode pad 120 is formed on the face of the second semiconductor chip 100 opposite to the first semiconductor chip 200. The electrode pad 120 is positioned in the same layer as the conductor patterns 122. The electrode pads 220 and 120 are connected to each other through a bump 300 as a connection member. The through-vias 230 and 130, the electrode pads 220 and 120, and the bump 300 are positioned in a first region 10 corresponding to a region in which an EBG structure 20 is not formed.

In this configuration, a unit cell 50 of the EBG structure 20 is formed by one island-shaped conductor pattern of the first conductor patterns 222 cut into conductor pieces, one of the bumps 302, one island-shaped conductor pattern of the conductor patterns 122, and regions where the first conductor plane 112 and the substrate of the first semiconductor chip 200 overlap one of the first conductor pattern 222 cut into conductor pieces in a plan view. The unit cell 50 is two-dimensionally repeated in a plan view, and for example, is periodically arranged.

In the case of arranging “repetitive” unit cells 50, in unit cells 50 located next to each other, it is preferable that a distance between the same vias (a distance between the centers) be set to be within a half of a wavelength λ of electromagnetic waves serving as an assumed noise. The meaning of “repetitive” includes also a case in which a part of the configurations in any unit cell 50 are deficient. In a case where the unit cells 50 have a two-dimensional arrangement, the meaning of “repetitive” includes also a case in which the unit cells 50 are partially deficient. The meaning of “periodic” includes a case in which a part of constituent elements are deviated in a part of the unit cells 50 or a case in which arrangement itself of the part of the unit cells 50 is deviated. That is, defects of some degrees are permitted in the “periodicity”, because despite a loss of periodicity in a strict sense, the metamaterial properties may be obtained as long as the unit cells 50 are repetitively arranged. Assumed causes of the occurrence of the defects include a case in which an interconnect or a via is made to penetrate between the unit cells, a case in which the unit cells may not be placed due to the existing via or pattern in the case of adding a metamaterial structure to the existing interconnect layout, a manufacturing error, a case in which the existing via or pattern is used as a part of the unit cells, and the like.

The EBG structure 20 is a so-called mushroom-type EBG structure, and the first conductor plane 112 corresponds to a conductor plane connected to the mushroom. The vias 114, the conductor patterns 122, and the bumps 302 correspond to an inductance portion of the mushroom, and the first conductor patterns 222 cut into conductor pieces correspond to a head portion of the mushroom. The substrate (third conductor) of the first semiconductor chip 200 corresponds to a second conductor plane opposite to the mushroom and becomes a ground line. In this configuration, the magnitude of each capacitance of the EBG structure 20 is controlled by a gap between the first semiconductor chip 200 and the second semiconductor chip 100, and the size and the arrangement of the first conductor patterns 222 cut into conductor pieces. The inductance components of the EBG structure 20 are controlled by the length and the diameter of the vias 114. A band gap of the EBG structure 20 may be adjusted by adjusting these physical factors.

Encapsulation resin 640 is injected between the first semiconductor chip 200 and the second semiconductor chip 100. As a result, the magnitude of the capacitance of the EBG structure 20 may be adjusted by adjusting a material of the encapsulation resin 640.

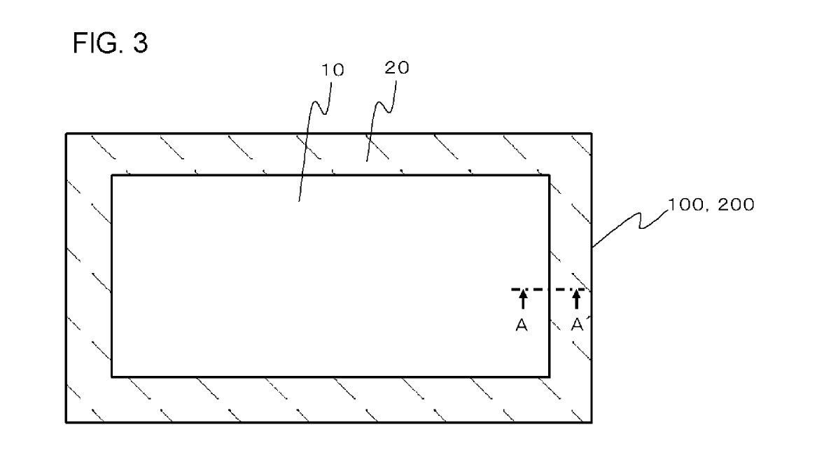

FIG. 3 shows a planar schematic diagram illustrating a positional relationship between the first region and the EBG structure 20. As shown in FIG. 2, the through-vias 230 and 130, the electrode pads 220 and 120, and the bump 300 are provided in the first region 10. The first region 10 is positioned at a central side of the first semiconductor chip 200 compared to the EBG structure 20. The EBG structure 20 is formed to surround the first region 10. FIG. 2 corresponds to a cross-sectional diagram taken along A-A′ in FIG. 3.

Next, an operation and an effect of this embodiment will be described. In this embodiment, the EBG structure 20 is formed using the first conductor patterns 222 cut into conductor pieces and the conductor patterns 122. The first conductor patterns 222 cut into conductor pieces are formed in the first semiconductor chip 200. The conductor patterns 122 are formed in the second semiconductor chip 100. Thus, the EBG structure 20 is formed in the space between the first semiconductor chip 200 and the second semiconductor chip 100. As a result, noise is prevented from propagating in the space and radiating to the outside.

Examples of a source for the noise include the bump 300. If several semiconductor chips 600 are vertically and adjacently stacked like this embodiment, the plurality of semiconductor chips 600 may be switched concurrently, and thus the noise radiated from the bump 300 increases. If the EBG structure 20 is designed in such a manner that a frequency of the noise radiated from the bump 300 is included in the band gap of the EBG structure 20, the noise radiated from the bump 300 is prevented from leaking from the space between the first semiconductor chip 200 and the second semiconductor chip 100.

In this embodiment, the first conductor patterns 222 cut into conductor pieces are opposite to the substrate of the first semiconductor chip 200 to be the second conductor plane. The insulating layer 210 is interposed between the first conductor patterns 222 and the substrate of the first semiconductor chip 200. As a result, in the EBG structure 20, a capacitance component that mainly determines a band gap may be calculated as a simple parallel plate capacitance formed by the first conductor patterns 222 cut into conductor pieces and the substrate of the first semiconductor chip 200. Thus, the design of the capacitance in the EBG structure 20 becomes easy. There is a flexibility of adjusting the thickness and the material of the insulating layer 210 particularly in this embodiment, and therefore the above-described effect increases.

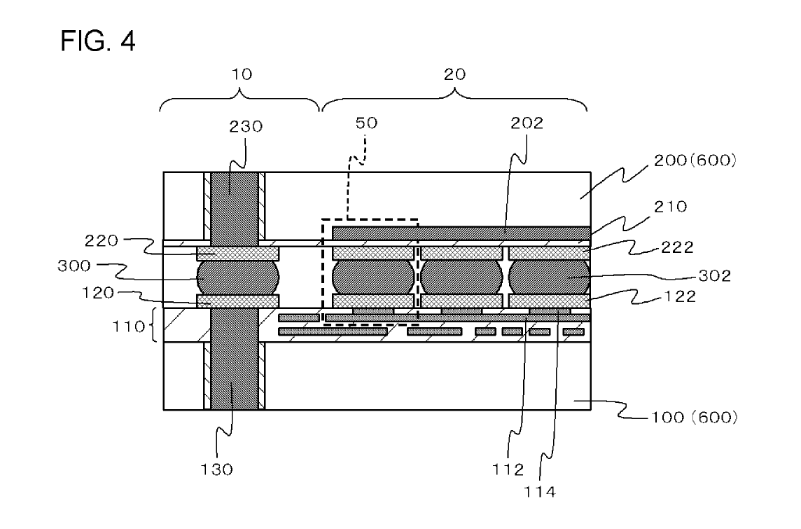

FIG. 4 shows a cross-sectional diagram illustrating a configuration of a semiconductor device according to a second embodiment. This drawing corresponds to FIG. 2 in the first embodiment. The semiconductor device according to this embodiment has the same configuration as the semiconductor device according to the first embodiment except that the substrate of the first semiconductor chip 200 is provided with an impurity region 202 (third conductor) in the face opposite to the second semiconductor chip 100. The impurity region 202 extends in the region overlapping the plurality of island-shaped conductor patterns making up the first conductor patterns 222 cut into conductor pieces in a plan view. In the EBG structure 20, the impurity region 202 corresponds to a second conductor plane in a mushroom-type EBG structure.

According to this embodiment, the same effect as the first embodiment may be obtained. Additionally, an effective capacitance may be adjusted by adjusting the impurity concentration of the impurity region 202, and thus the band gap of the EBG structure 20 may be controlled. Especially in the low resistance, capacitance per unit area may be enhanced. Thus, the band gap of the EBG structure 20 may be shifted toward a low frequency side even with the same area.

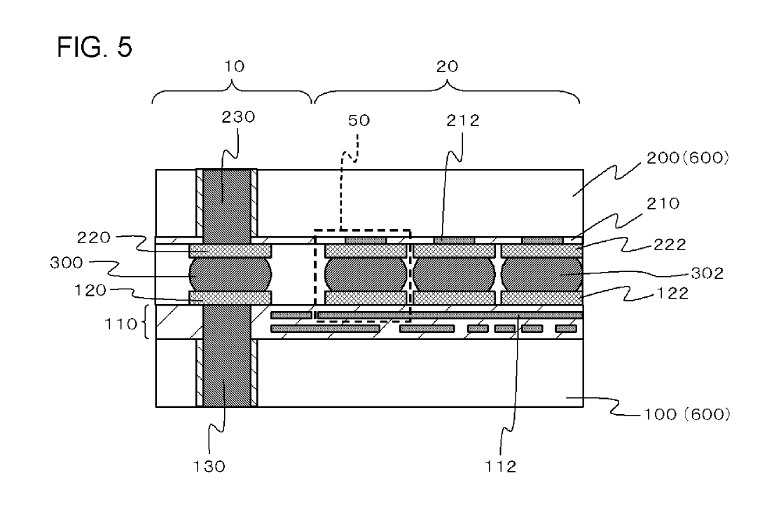

FIG. 5 shows a cross-sectional diagram illustrating a configuration of a semiconductor device according to a third embodiment. This drawing corresponds to FIG. 2 in the first embodiment. The semiconductor device according to this embodiment has the same configuration as the semiconductor device according to the first embodiment except for the following aspects.

First, the second semiconductor chip 100 is not provided with the vias 114. The first semiconductor chip 200 has a plurality of vias 212. The plurality of vias 212 are provided in the insulating layer 210, and connect the first conductor patterns 222 cut into conductor pieces and formed in the plurality of island-shaped conductor patterns, to the substrate of the first semiconductor chip 200. The second conductor patterns 122 are not directly connected to other conductors included in the second semiconductor chip 100.

In this embodiment, the EBG structure 20 is also a so-called mushroom-type EBG structure, and has a structure vertically inverted from the structure of the EBG structure 20 in the first embodiment. That is, the EBG structure 20 has a structure in which the first conductor plane 112 (third conductor) is opposite to the head of the mushroom. The substrate of the first semiconductor chip 200 corresponds to the conductor plane connected to the mushroom. The vias 212, the first conductor patterns 222, and the bumps 302 correspond to an inductance portion of the mushroom. The second conductor patterns 122 cut into conductor pieces correspond to a head portion of the mushroom. The plurality of the second conductor patterns 122 are electrically connected to each other through the plurality of bumps 302, the plurality of the first conductor patterns 222, the plurality of vias 212, and the substrate of the first semiconductor chip 200.

According to this embodiment, the same effect as the first embodiment may be obtained.

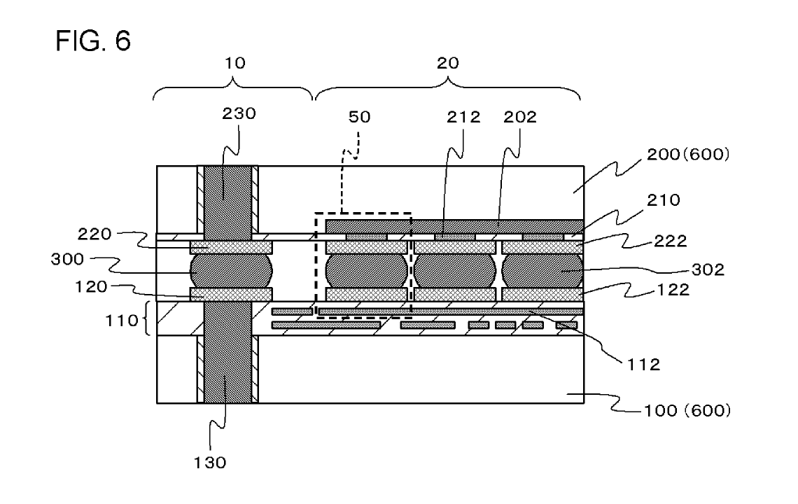

FIG. 6 shows a cross-sectional diagram illustrating a configuration of a semiconductor device according to a fourth embodiment. This drawing corresponds to FIG. 5 in the third embodiment. The semiconductor device according to this embodiment has the same configuration as the semiconductor device according to the third embodiment except that the substrate of the first semiconductor chip 200 is provided with an impurity region 202 in the face opposite to the second semiconductor chip 100. The impurity region 202 extends in the region overlapping the plurality of island-shaped conductor patterns making up the first conductor patterns 222 in a plan view. In the EBG structure 20, the impurity region 202 corresponds to a lower-side conductor plane in the mushroom-type EBG structure. The plurality of the second conductor patterns 122 are electrically connected to each other through the plurality of bumps 302, the plurality of the first conductor patterns 222, the plurality of vias 212, and the impurity region 202.

According to this embodiment, the same effect as the third embodiment may be obtained. Additionally, resistance of the lower-side conductor plane in the mushroom-type EBG structure may be made to be low. As a result, rising and falling of the band gap of the EBG structure 20 may be steepened.

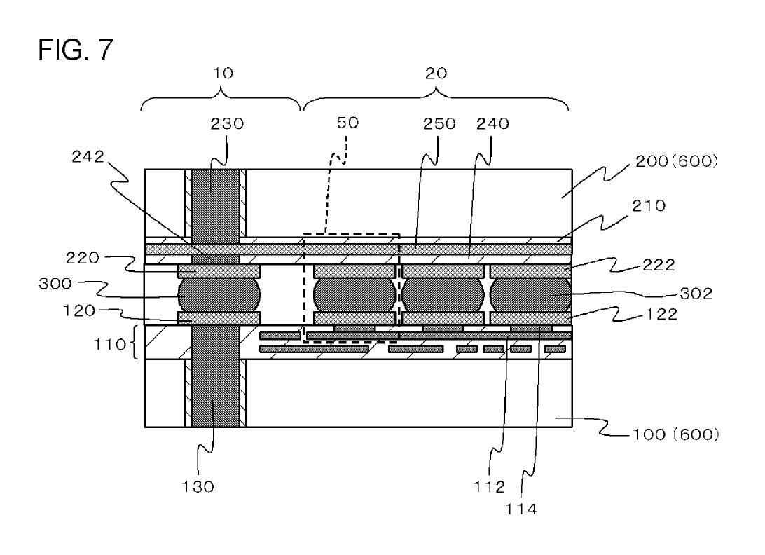

FIG. 7 shows a cross-sectional diagram illustrating a configuration of a semiconductor device according to a fifth embodiment. This drawing corresponds to FIG. 2 in the first embodiment. The semiconductor device according to this embodiment has the same configuration as the semiconductor device according to the first embodiment except for the following aspects.

First, the first semiconductor chip 200 is provided with a conductor pattern 250 (third conductor) and an insulating layer 240. The conductor pattern 250 has a sheet shape and is formed on the insulating layer 210. The insulating layer 240 is formed on the conductor pattern 250. The plurality of island-shaped conductor patterns making up the first conductor patterns 222 cut into conductor pieces are formed on the insulating layer 240.

In this embodiment, the through-via 230 is either a power supply line or a ground line, and is connected to the electrode pad 220 through the conductor pattern 250 and a conductor pattern 242 provided in the insulating layer 240. That is, the conductor pattern 250 is connected to the through-via 230.

In this embodiment, the EBG structure 20 is a so-called mushroom-type EBG structure like the first embodiment. Nevertheless, instead of the substrate of the first semiconductor chip 200, the conductor pattern 250 corresponds to the upper-side conductor plane.

According to this embodiment, the same effect as the first embodiment may be also obtained. Additionally, the capacitance formed by the first conductor patterns 222 and the conductor pattern 250 may be controlled by the material and the thickness of the insulating layer 240. Thus, the control of the band gap may be further easy.

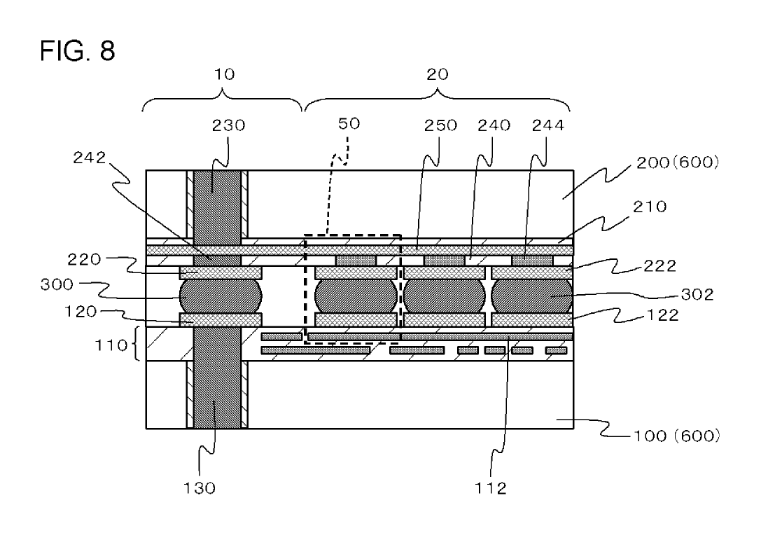

FIG. 8 shows a cross-sectional diagram illustrating a configuration of a semiconductor device according to a sixth embodiment. This drawing corresponds to FIG. 7 in the seventh embodiment. The semiconductor device according to this embodiment has the same configuration as the semiconductor device according to the seventh embodiment except for the following aspects.

First, the second semiconductor chip 100 is not provided with the vias 114. The first semiconductor chip 200 has a plurality of vias 244. The plurality of vias 244 are provided in the insulating layer 240, and the second conductor patterns 122 cut into the conductor pieces are connected to the sheet-shaped conductor pattern 250 through the bumps 302 and the conductor patterns 222.

The EBG structure 20 is a so-called mushroom-type EBG structure and has a structure vertically inverted from the structure of the EBG structure 20 in the first embodiment, similarly to the third embodiment. That is, the first conductor plane 112 corresponds to a conductor plane opposite to the head of the mushroom. The conductor patterns 250 of the first semiconductor chip 200 correspond to the lower-side conductor plane. The vias 244, the conductor patterns 222, and the bumps 302 correspond to an inductance portion of the mushroom. The second conductor patterns 122 cut into conductor pieces correspond to the head portion of the mushroom. The plurality of the second conductor patterns 122 are electrically connected to each other through the plurality of bumps 302, the plurality of first conductor pattern 222, the plurality of vias 244, and the conductor pattern 250.

According to this embodiment, the same effect as the first embodiment may be obtained. Additionally, it is not necessary to change the multi-layer wiring of the second semiconductor chip 100. The EBG structure may be also formed on a semiconductor chip not designed for stacking.

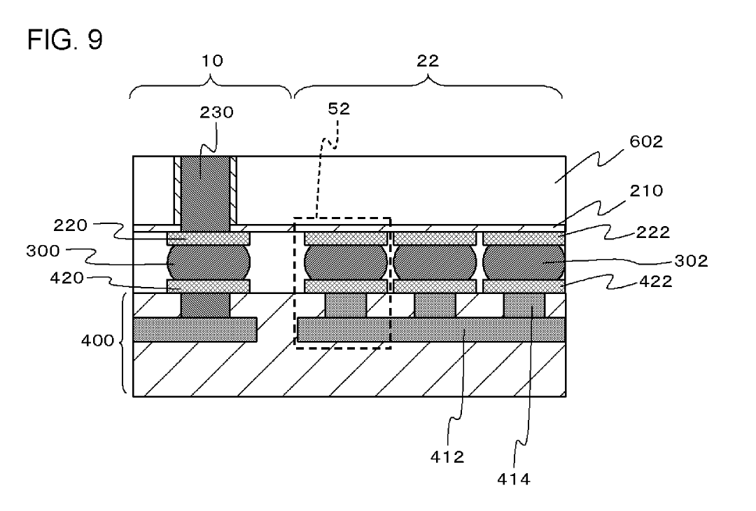

FIG. 9 shows a cross-sectional diagram illustrating a configuration of a semiconductor device according to a seventh embodiment. This semiconductor device is the same as any one of the first to sixth embodiments except that an EBG structure 22 is provided between the lowest semiconductor chip 602 in the semiconductor chips 600 and an interposer substrate 400.

In this embodiment, the semiconductor chip 602 has the same configuration as the first semiconductor chip 200, and is provided with the insulating layer 210, the electrode pad 220, the first conductor patterns 222 cut into conductor pieces, and the through-via 230.

The interposer substrate 400 is provided with second conductor patterns 422, vias 414, a planar conductor pattern 412, and an electrode pad 420. The electrode pad 420 is connected to the electrode pad 220 through a bump 300. The second conductor patterns 422, the vias 414, and the conductor pattern 412 have the same layout as the conductor patterns 122, the vias 114, and the first conductor plane 112 in the first embodiment in a plan view. The conductor pattern 412 is connected to either a power supply line or a ground line, for example, the power supply line.

In this embodiment, a unit cell 52 of an EBG structure 22 has a mushroom structure similarly to the unit cell 50 in the first embodiment. Specifically, the conductor pattern 412 corresponds to a conductor plane connected to the mushroom structure. Vias 414, the second conductor patterns 422, and the bumps 302 correspond to an inductance portion of the mushroom. The first conductor patterns 222 cut into conductor pieces correspond to a head portion of the mushroom. The substrate of the first semiconductor chip 200 corresponds to a conductor plane opposite to the head of the mushroom. The EBG structure 22 is formed to surround the first region 10. The plurality of first conductor patterns 222 are electrically connected to each other through the plurality of bumps 302, the plurality of conductor patterns 412, the plurality of vias 414, and the conductor pattern 412.

According to this embodiment, the same effect as the first embodiment may be obtained. Additionally, the EBG structure 22 is formed using the first conductor patterns 222 cut into conductor pieces and the second conductor patterns 422. The first conductor patterns 222 cut into conductor pieces are formed in the semiconductor chip 602. The second conductor patterns 422 are formed in the interposer substrate 400. Thus, the EBG structure 22 is formed in the space between the semiconductor chip 602 and the interposer substrate 400. As a result, noise is prevented from propagating in the space and radiating to the outside.

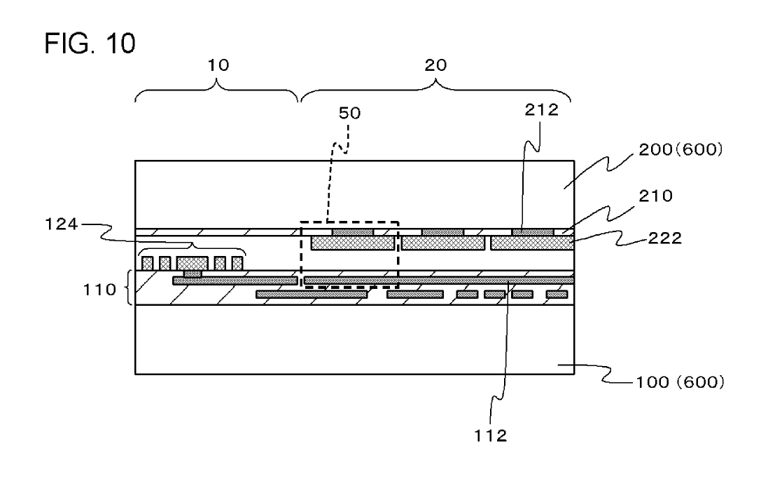

FIG. 10 shows a cross-sectional diagram illustrating a configuration of a semiconductor device according to an eighth embodiment. This semiconductor device has the same configuration as that according to the third embodiment shown in FIG. 5 except for the following aspects.

First, the first semiconductor chip 200 and the second semiconductor chip 100 transmit and receive a signal between each other by performing communication between an inductor (not shown) formed in the first semiconductor chip 200 and an inductor 124 formed in the second semiconductor chip 100. As a result, the through-vias 130 and 230, and the bump 300 shown in FIG. 5 are not formed. This leads to no formation of the bump 302. That is, a conductor for connecting the first conductor patterns 222 to the first conductor plane 112 is not provided in the space between the first semiconductor chip 200 and the second semiconductor chip 100.

The EBG structure 20 does not have the second conductor patterns 122 and the vias 114. The EBG structure 20 in this embodiment is a mushroom-type EBG structure, but the first conductor plane 112 corresponds to a conductor plane opposite to the head of the mushroom. The substrate of the first semiconductor chip 200 corresponds to a conductor plane connected to the mushroom. The vias 212 correspond to an inductance portion of the mushroom. The first conductor patterns 222 cut into conductor pieces correspond to the head portion of the mushroom. The plurality of first conductor patterns 222 are electrically connected to each other through the plurality of vias 212 and the substrate of the first semiconductor chip 200.

According to this embodiment, the same effect as the third embodiment may be obtained. Additionally, there is no need for a bump connection, and as a result, a fabrication process may be simple.

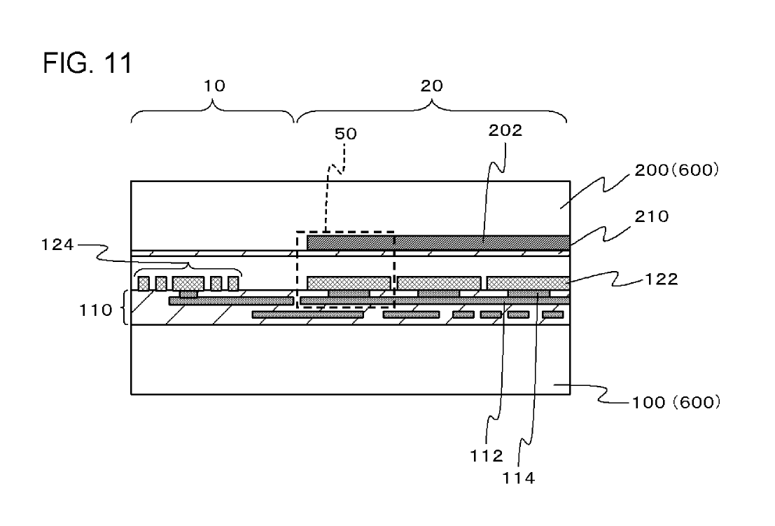

FIG. 11 shows a cross-sectional diagram illustrating a configuration of a semiconductor device according to a ninth embodiment. This semiconductor device has the same configuration as the semiconductor device according to the eighth embodiment shown in FIG. 10 except the configuration of the EBG structure 20.

The EBG structure 20 in this embodiment does not include the vias 212 and the first conductor patterns 222. Instead, the EBG structure 20 includes the impurity region 202, second conductor patterns 122 cut into conductor pieces, and the vias 114. The configurations of the impurity region 202, the second conductor patterns 122 cut into conductor pieces, and the vias 114 are similar to those shown in FIG. 4 in the second embodiment.

This EBG structure 20 is a mushroom-type EBG structure, but the impurity region 202 corresponds to a conductor plane opposite to the head of the mushroom. The first conductor plane 112 corresponds to a conductor plane connected to the mushroom. The vias 114 correspond to an inductance portion of the mushroom. The second conductor patterns 122 cut into conductor pieces correspond to a head portion of the mushroom. The plurality of second conductor patterns 122 are electrically connected to each other through the plurality of vias 114 and the conductor pattern 112.

According to this embodiment, the same effect as the eighth embodiment may be obtained. Additionally, an effective capacitance may be adjusted by the impurity region 202, and thus the band gap of the EBG structure 20 may be controlled. Especially in the low resistance, capacitance per unit area may be enhanced. Thus, the band gap of the EBG structure 20 may be shifted toward a low frequency side even with the same area. In this embodiment, the impurity region 202 is not necessarily provided. In this case, the substrate of the first semiconductor chip 200 corresponds to an upper-side conductor plane in the mushroom-type EBG structure.

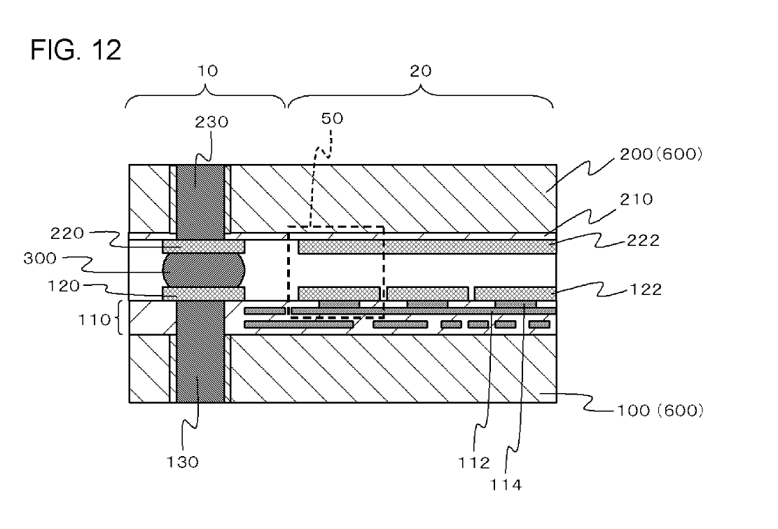

FIG. 12 shows a cross-sectional diagram illustrating a configuration of a semiconductor device according to a tenth embodiment. This semiconductor device has the same configuration as the semiconductor device according to the first embodiment except the configuration of the EBG structure 20.

First, the first conductor pattern 222 (third conductor) does not have an island shape and is a sheet-shaped conductor pattern. The bumps 302 are not provided.

This EBG structure 20 is a mushroom-type EBG structure, but the planar first conductor pattern 222 corresponds to a conductor plane opposite to a head of the mushroom. The first conductor plane 112 corresponds to a lower-side conductor plane. The vias 114 corresponds to an inductance portion of the mushroom. The second conductor patterns 122 cut into conductor pieces correspond to a head portion of the mushroom.

According to this embodiment, the same effect as the first embodiment may be obtained. Additionally, since the number of bump connection portions is small, a yield ratio of the semiconductor device may be enhanced.

FIG. 15 shows a cross-sectional diagram illustrating a configuration of a semiconductor device according to an eleventh embodiment. In this semiconductor device, the semiconductor chip 610 is mounted on the interpose substrate 400 in a flip-chip manner. The semiconductor chip 610 is mounted on the interpose substrate 400 in a manner such that the face in which a multi-layer wiring 650 and a redistribution layer are formed faces downwardly. Electrode pads 628 of the redistribution layer are connected to electrode pads 420 of the interpose substrate 400 through the bumps 300. The electrode pad 628, the bumps 300, and the electrode pads 420 are positioned in the first region 14.

A plurality of island-shaped conductor patterns functioning as conductor pieces 626 are provided in the redistribution layer. These plurality of island-shaped conductor patterns are connected to island-shaped second conductor patterns 422 of the interposer substrate 400 through the bumps 302. A configuration of the interpose substrate 400 is similar to that shown in the seventh embodiment.

The multi-layer wiring 650 includes a sheet-shaped conductor plane 616. The conductor plane 616 is formed in the interconnect layer below the conductor pieces 626, and is located in the region overlapping the conductor plane 616 in a plan view.

A unit cell 56 of an EBG structure 24 has the same mushroom structure as the unit cell 50 in the first embodiment. Specifically, the conductor pattern 412 corresponds to a conductor plane connected to the mushroom. The vias 414, the second conductor patterns 422, and the bumps 302 correspond to an inductance portion of the mushroom. The conductor pieces 626 correspond to a head portion of the mushroom. The conductor plane 616 corresponds to a conductor plane opposite to the head of the mushroom. In addition, the EBG structure 24 is formed to surround the first region 14.

In this embodiment, the EBG structure 24 is formed using the conductor pieces 626 and the second conductor patterns 422. The conductor pieces 626 are formed on the semiconductor chip 610. The second conductor patterns 422 are formed on the interposer substrate 400. Thus, the EBG structure 24 is formed in the space between the semiconductor chip 610 and the interpose substrate 400. As a result, noise is prevented from propagating in the space and radiating to the outside.

Hereinbefore, the embodiments of the invention have been described with reference to the attached drawings, but these are illustrative only and various configurations other than the above-described configuration may be adopted. For example, the configurations of the EBG structures 20 to 24 are not limited to the above-described embodiments, and an arbitrary structure exhibiting EBG properties may be applied as the EBG structures 20 to 24.

The present patent application claims priority from Japanese Patent Application No. 2009-257070 filed on Nov. 10, 2009, the disclosure of which is incorporated herein by reference.

1. A semiconductor device, comprising:
a mounted object;
a first semiconductor chip mounted over the mounted object;
a plurality of first conductors repeatedly provided to one element selected from a group consisting of the first semiconductor chip and the mounted object;
a second conductor provided to the other element selected from the group consisting of the first semiconductor chip and the mounted object, the second conductor being opposite to the plurality of first conductors; and
a plurality of connection members provided at a space between the mounted object and the first semiconductor chip, the plurality of connection members being electrically connecting the plurality of first conductors to the second conductor,
wherein the plurality of first conductors are electrically connected to each other through the plurality of connection members and the second conductor.

2. The semiconductor device according to claim 1, further comprising:
a third conductor provided to the one element, the third conductor being located at an inner layer of the one element and below the first conductors, the third conductor being opposite to the plurality of first conductors, the third conductor being not electrically connected to the first conductors in the one element.

3. The semiconductor device according to claim 1,
wherein the second conductor is formed at an inner layer of the other element,
the semiconductor device further comprising:
a via provided to the other element and electrically connecting the second conductor to the connection member.

4. The semiconductor device according to claim 1,
wherein the other element is the first semiconductor chip, and
the second conductor is a substrate of the first semiconductor chip.

5. The semiconductor device according to claim 1,
wherein one element selected from a group consisting of the first conductor and the second conductor is connected to a power supply, and the other element is connected to a ground.

6. A semiconductor device, comprising:
a mounted object;
a first semiconductor chip mounted over the mounted object;
a plurality of first conductors repeatedly provided to one element selected from a group consisting of the mounted object and the first semiconductor chip;
a second conductor provided to the one element, the second conductor being opposite to the plurality of first conductors;
a plurality of vias connecting the plurality of first conductors to the second conductor,
wherein the plurality of first conductors are electrically connected to each other through the plurality of vias and the second conductor.

7. The semiconductor device according to claim 6,
wherein the one element is the first semiconductor chip, and
the second conductor is a substrate of the first semiconductor chip.

8. The semiconductor device according to claim 6, further comprising:
a third conductor provided to the other element selected from the group consisting of the mounted object and the first semiconductor chip, the third conductor being opposite to the plurality of first conductors.

9. The semiconductor device according to claim 1, further comprising:
a first external connection terminal formed over a face of the first semiconductor chip opposite to the mounted object;
a second external connection terminal formed over a face of the mounted object opposite to the first semiconductor chip; and
a connection member connecting the first external connection terminal to the second external connection terminal,
wherein the first conductor and the second conductor are formed to surround the first external connection terminal, the second external connection terminal, and the connection member in a plan view.

10. The semiconductor device according to claim 1,
wherein the first conductor is formed over a face of the first semiconductor chip opposite to the mounted object.

11. The semiconductor device according to claim 1,
wherein the first conductor is formed over a face of the mounted object opposite to the first semiconductor chip.

12. The semiconductor device according to claim 1,
wherein the mounted object is an interposer substrate.

13. The semiconductor device according to claim 1,
wherein the mounted object is a second semiconductor chip.

14. A noise suppressing method, comprising:
providing a first conductor to a mounted object over which a semiconductor chip is mounted; and
providing a second conductor to the semiconductor chip, the second conductor being located at a region opposite to the first conductor,
wherein at least one element selected from a group consisting of the first conductor and the second conductor is formed to have a repetitive structure, and an Electromagnetic Band Gap (EBG) structure is formed by using the first conductor and the second conductor,
the method being preventing a noise from leaking from a space between the mounted object and the first semiconductor chip.

15. The semiconductor device according to claim 6, further comprising:
a first external connection terminal formed over a face of the first semiconductor chip opposite to the mounted object;
a second external connection terminal formed over a face of the mounted object opposite to the first semiconductor chip; and
a connection member connecting the first external connection terminal to the second external connection terminal,
wherein the first conductor and the second conductor are formed to surround the first external connection terminal, the second external connection terminal, and the connection member in a plan view.

16. The semiconductor device according to claim 6,
wherein the first conductor is formed over a face of the first semiconductor chip opposite to the mounted object.

17. The semiconductor device according to claim 6,
wherein the first conductor is formed over a face of the mounted object opposite to the first semiconductor chip.

18. The semiconductor device according to claim 6,
wherein the mounted object is an interposer substrate.

19. The semiconductor device according to claim 6,
wherein the mounted object is a second semiconductor chip.

20. The semiconductor device according to claim 2,
wherein the second conductor is formed at an inner layer of the other element,
the semiconductor device further comprising:
a via provided to the other element and electrically connecting the second conductor to the connection member.
